(19) United States
(12) Patent Application Publication
(10) Pub. No.: US 2007/0096267 A1
(43) Pub. Date: May 3, 2007

(54) MOTHERBOARD WITH SELECTIVE CHIP LAYOUT

(75) Inventor: Miao He, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,415

(22) Filed: Aug. 4, 2006

(30) Foreign Application Priority Data
Oct. 27, 2005 (CN) 200510100773.8

(51) Int. Cl. H01L 23/495

(52) U.S. Cl. 257/666

(57) ABSTRACT

A motherboard with selective chip layout includes a first chip mounting area for receiving a first chip, a plurality of first pads located at edges of the first chip mounting area, for attachment of soldering pins of the first chip thereon, a second chip mounting area for receiving a second chip, and a plurality of second pads located at edges of the second chip mounting area, for attachment of soldering pins of the second chip thereon. The second chip mounting area and the second pads are positioned within the first chip mounting area.

### FIELD OF THE INVENTION

The present invention relates to a motherboard, and particularly to a motherboard which readily and selectively receives different chips thereon.

### DESCRIPTION OF RELATED ART

With the development of wide-band technology, bandwidth speed is increasing.

Generally, in keeping with users' demands, two mounting areas for selectively supporting one of two ethernet control chips with two different transmission rates on a same motherboard so that the motherboard selectively supports 100 Mbps and 1000 Mbps transmission rates is provided.

Referring to FIG. 2, a conventional motherboard 100 with a layout for two different chips is shown. The motherboard 100 includes a chip mounting area 20 for accommodating a 1000 Mbps transmission rate ethernet control chip, and a chip mounting area 50 for accommodating a 100 Mbps transmission rate ethernet control chip. A plurality of pads 30 are arranged at four edges of the chip mounting area 20, for mounting of the 1000 Mbps transmission rate ethernet control chip thereon. A plurality of pads 60 are arranged at four edges of the chip mounting area 50, for mounting of the 100 Mbps transmission rate ethernet control chip thereon. Six pads 713 are used for receiving 0603-type resistors, two pads 714 are used for receiving 0603-type capacitors, a pad 715 is used for receiving a 0805-type capacitor, and a pad 716 is used for receiving a 0805-type inductor. Each pad 713, 714, 715, and 716is connected to corresponding pad 60.

However, space on the motherboard 100 is limited. When both the chip mounting areas 20 and 50 are defined on the same motherboard 100, available layout space of the motherboard 100 is decreased.

What is needed, therefore, is a motherboard having a space-saving layout for ethernet control chips that is capable of selectively supporting different ethernet control chips with different transmission rates.

### SUMMARY OF THE INVENTION

An exemplary motherboard with a selective chip layout includes a first chip mounting area for receiving a first chip, a plurality of first pads located at edges of the first chip mounting area, for attachment of soldering pins of the first chip thereon, a second chip mounting area for receiving a second chip, and a plurality of second pads located at edges of the second chip mounting area, for attachment of soldering pins of the second chip thereon. The second chip mounting area and the second pads are positioned within the first chip mounting area.

Other advantages and novel features will become more apparent from the following detailed description, in which:

### BRIEF DESCRIPTION OF THE DRAWINGS

FIG. 1 is a schematic view of a motherboard with a layout for ethernet control chips in accordance with a preferred embodiment of the present invention; and

FIG. 2 is a schematic view of a conventional motherboard with a layout for ethernet control chips.

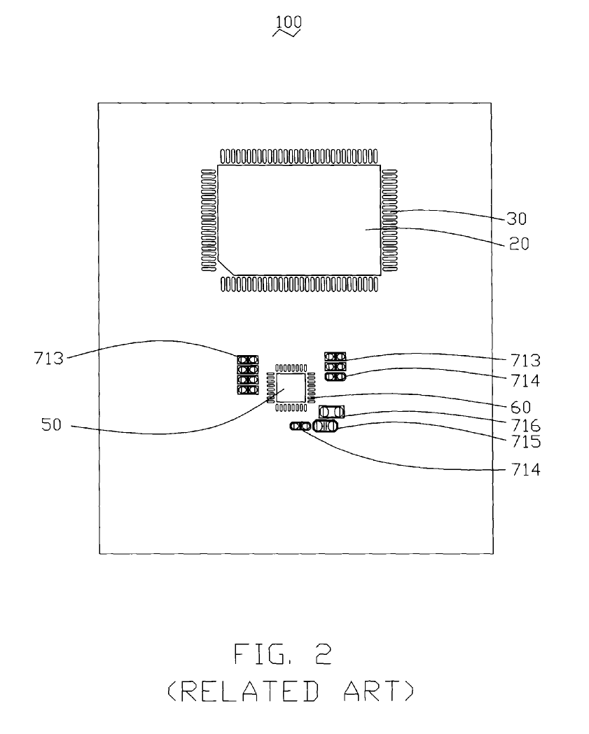

### DETAILED DESCRIPTION OF THE INVENTION

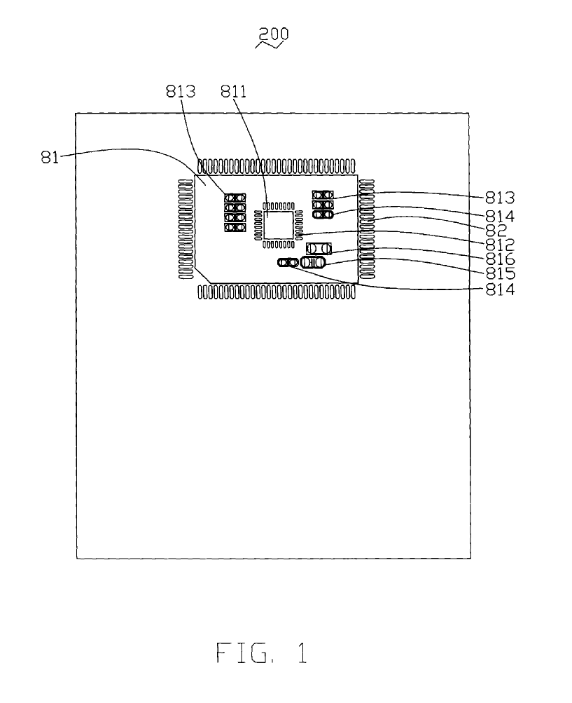

FIG. 1 shows a schematic view of a circuit assembly like a motherboard 200 with a layout for electronic components like ethernet control chips in accordance with a preferred embodiment of the present invention. The motherboard 200 includes a chip mounting area 81, a chip mounting area 811 located within the chip mounting area 81, a plurality of pads 82 located along four edges of the chip mounting area 81, and a plurality of pads 812 located along four edges of the chip mounting area 811 and positioned within the chip mounting area 81. Six pads 813 are arranged for receiving 0603-type resistors, two pads 814 are arranged for receiving 0603-type capacitors, a pad 815 is arranged for receiving a 0805-type capacitor, and a pad 816 is arranged for receiving a 0805-type inductor. Each pad 813, 814, 815, and 816, is positioned within the chip mounting area 81, and is connected to corresponding pad 812.

The chip mounting area 81 is arranged for accommodating a first ethernet control chip with a 1000 Mbps transmission rate. The pads 82 are used for receiving soldering pins of the first ethernet control chip thereon. The chip mounting area 811 is arranged for accommodating a second ethernet control chip with 100 Mbps transmission rate. The pads 812 are used for receiving soldering pins of the second ethernet control chip thereon.

A distance from each pad 813, 814, 815, or 816 to a nearest edge of the chip mounting area 81 is generally greater than 2 mm, so as to prevent short circuits from occurring with the pads 82 when electronic components are soldered on the pads 813, 814, 815, or 816.

In the embodiment, the chip mounting area 811, and the pads 812, 813, 814, 815, and 816 are located within the chip mounting area 81. Thus, The motherboard 200 selectively supports two ethernet control chips with two different transmission rates according to individual requirements in a space-saving manner.

It is believed that the present embodiment and its advantages will be understood from the foregoing description, and it will be apparent that various changes may be made thereto without departing from the spirit and scope of the invention or sacrificing all of its material advantages, the example hereinbefore described merely being a preferred or an exemplary embodiment of the invention.

What is claimed is:

1. A motherboard with a selective chip layout, comprising:
a first chip mounting area for receiving a first chip;
a plurality of first pads located at edges of the first chip mounting area, for attachment of
soldering pins of the first chip thereon;
a second chip mounting area for receiving a second chip; and
a plurality of second pads located at edges of the second chip mounting area, for attachment of soldering pins of the second chip thereon, the second chip mounting area and the second pads being positioned within the first chip mounting area.

2. The motherboard as claimed in claim 1, further comprising pads arranged for receiving resistors, capacitors, and an inductor, the pads being positioned within the first chip mounting area, each of the pads being connected to corresponding second pad.

3. The motherboard as claimed in claim 2, wherein a distance between a nearest edge of the first chip mounting area and each of the pads is generally greater than 2 mm.

4. A method for a selective chip layout, comprising the steps of:
setting a first chip mounting area arranged on a motherboard, for receiving a first chip;
arranging a plurality of first pads located at edges of the first chip mounting area, for attachment of soldering pins of the first chip thereon;
forming a second chip mounting area arranged within the first chip mounting area, for receiving a second chip; and
arranging a plurality of second pads located at edges of the second chip mounting area, for attachment of soldering pins of the second chip thereon, the second pads being located within the first chip mounting area.

5. The method as claimed in claim 4, further comprising the step of providing pads arranged for receiving resistors, capacitors, and an inductor, the pads being positioned within the first chip mounting area, each of the pads being connected to corresponding second pad.

6. The method as claimed in claim 5, wherein a distance between a nearest edge of the first chip mounting area and each of the pads is generally greater than 2 mm.

7. A method for arranging a layout on a circuit assembly for electronic components, comprising the steps of:
defining a first mounting area on a circuit assembly for mounting of a first electronic component;
placing a plurality of first pads on said circuit assembly around said first mounting area so as to electrically connect said circuit assembly with said first electronic component;
defining a second mounting area, sized smaller than said first mounting area, on said circuit assembly within said first mounting area for mounting of a second electronic component sized smaller than said first electronic component;
placing a plurality of second pads on said circuit assembly within said first mounting area around said second mounting area so as to electrically connect said circuit assembly with said second electronic component; and
forming a clearance between said plurality of second pads and said plurality of first pads.

8. The method as claimed in claim 7, wherein a distance of said clearance is greater than 2 mm.
